(19) United States
(12) Patent Application Publication
(10) Pub. No.: US 2019/0326403 A1
(43) Pub. Date: Oct. 24, 2019

(54) THIN FILM DIODE BASED BACK-END TEMPERATURE SENSORS

(71) Applicant: INTEL CORPORATION, Santa Clara, CA (US)

(72) Inventors: Ravi Pillarisetty, Portland, OR (US); Prashant Majhi, San Jose, CA (US); Abhishek A. Sharma, Hillsboro, OR (US); Elijah V. Karpov, Portland, OR (US); Brian S. Doyle, Portland, OR (US); Willy Rachmady, Beaverton, OR (US); Gilbert Dewey, Hillsboro, OR (US); Jack T. Kavalieros, Portland, OR (US)

(73) Assignee: INTEL CORPORATION, Santa Clara, CA (US)

(21) Appl. No.: 15/956,604

(22) Filed: Apr. 18, 2018

(51) Int. Cl. H01L 29/24; H01L 29/861; G01K 7/34; H01L 29/16; H01L 29/20

(52) U.S. Cl. CPC H01L 29/24; H01L 29/861; H01L 29/20; H01L 29/16; G01K 7/343

(57) ABSTRACT

Electronic devices, integrated circuit device structures, and computing devices including thin film, diode-based temperature sensors are disclosed. An electronic device includes a diode including diode materials between a first contact and a second contact, a device layer of an integrated circuit device structure, and at least a portion of an interlayer dielectric between the diode and the device layer.

### BACKGROUND

Temperature fluctuations in integrated circuits sometimes affect certain devices within these integrated circuits differently from other devices within these integrated circuits. As a result, the operational temperature range specified for a given integrated circuit may be limited by whichever device or devices reach operational extremities in response to the smallest temperature fluctuations.

### BRIEF DESCRIPTION OF THE DRAWINGS

FIG. 1 is a simplified plot illustrating current-voltage characteristics of a diode for different temperatures.

FIGS. 2A and 2B illustrate an example of p-n junction diodes in an integrated circuit device structure.

FIG. 2A is a simplified plan view of the integrated circuit device structure.

FIG. 2B is a simplified cross-sectional view of the integrated circuit device structure taken through line 2B of FIG. 2A.

FIGS. 3A and 3B illustrate an example of p-n junction diodes in an integrated circuit device structure.

FIG. 4 is a simplified cross-sectional view of an electronic device, according to some embodiments.

FIG. 5 is a simplified cross-sectional view of a Shottky diode, according to some embodiments.

FIG. 6 is a simplified cross-sectional view of a p-n junction diode, according to some embodiments.

FIG. 7 is a simplified block diagram of an electronic device, according to some embodiments.

FIG. 8 illustrates an interposer that includes one or more embodiments of the disclosure.

FIG. 9 illustrates a computing device in accordance with one embodiment of the disclosure.

### DETAILED DESCRIPTION

Described herein are thin film, diode-based temperature sensors in interlayer dielectric (ILD) materials. In the following description, various aspects of the illustrative implementations will be described using terms commonly employed by those skilled in the art to convey the substance of their work to others skilled in the art. However, it will be apparent to those skilled in the art that the disclosure may be practiced with only some of the described aspects. For purposes of explanation, specific numbers, materials and configurations are set forth in order to provide a thorough understanding of the illustrative implementations. However, it will be apparent to one skilled in the art that the disclosure may be practiced without the specific details. In other instances, well-known features are omitted or simplified in order not to obscure the illustrative implementations.

Various operations will be described as multiple discrete operations, in turn, in a manner that is most helpful in understanding the disclosure. The order of the description, however, should not be construed to imply that these operations are necessarily order dependent. In particular, these operations need not be performed in the order of presentation.

The terms “over,” “under,” “between,” and “on,” as used herein, refer to a relative position of one material (e.g., region, structure, layer, etc.) or component with respect to other materials (e.g., regions, structures, layers, etc.) or components. For example, one material disposed over, under, or on another material may be directly in contact with the other material or may have one or more intervening materials. Moreover, one material disposed between two materials may be directly in contact with the two materials or may have one or more intervening materials. Also, to the extent that the terms “over,” “under,” and “on” imply a vertical orientation of some structure, it will be understood that a similar structure may be formed horizontally, diagonally, in some non-uniform or nonlinear orientation, or other orientation without departing from the scope of the disclosure.

Implementations of the disclosure may be formed or carried out on a substrate, such as a semiconductor substrate. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the disclosure.

Diode-based temperature sensors may be used to determine temperatures at specific locations within integrated circuits. Diodes can be used to determine temperature because diodes exhibit a temperature dependence in their current-voltage (I-V) characteristics. Specifically, the bandgap of a diode modulates the current of the diode as a function of the diode's thermal voltage (kT/q, where k is Boltzmann's constant (1.381×10⁻²³ Joules/Kelvin), T is the temperature of the diode, and q is the magnitude of the electrical charge of an electron).

FIG. 1 is a simplified plot 100 illustrating current-voltage characteristics of a diode for different temperatures. The plot 100 includes a zero degrees Celsius (0° C.) plot 102, a 50° C. plot 104, and a 100° C. plot 106 corresponding to I-V characteristics (forward current in amps (A) plotted against forward voltage bias across the diode in volts (V)) of the diode operating at 0° C., at 50° C., and at 100° C., respectively. As can be seen in the plot 100, the diode conducts current at an increasingly lower voltage bias as the temperature of the diode increases. As a result, correlating the voltage bias (e.g., the thermal voltage) of the diode at a specific turn-on current (e.g., a minimum threshold current) to a temperature of the diode may enable the diode to be used as a temperature sensor in integrated circuits.

One example of a diode that may be used as a temperature sensor is a p-n junction transistor. A p-n junction transistor includes a p-type semiconductor material (i.e., a semiconductor material that has been doped with impurities to create holes, or positive charge carriers) interfacing with an n-type semiconductor material (i.e., a semiconductor material that has been doped with impurities to create extra electrons, or negative charge carriers).

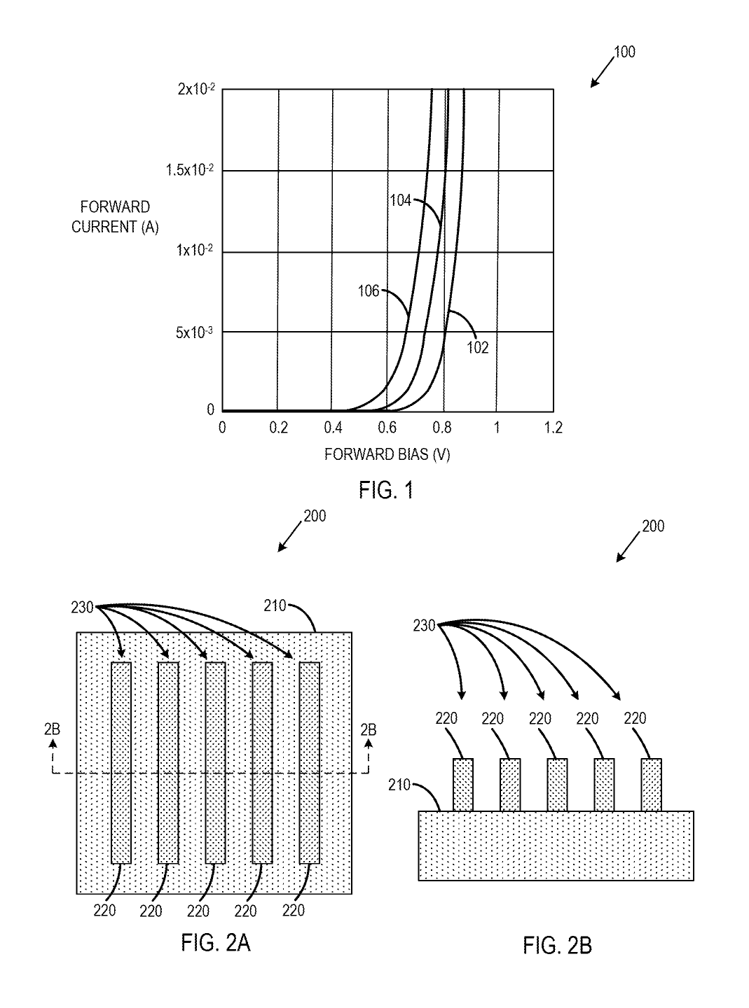

FIGS. 2A and 2B illustrate an example of p-n junction diodes 230 in an integrated circuit device structure 200. FIG. 2A is a simplified plan view of the integrated circuit device structure 200. FIG. 2B is a simplified cross-sectional view of the integrated circuit device structure 200 taken through line 2B of FIG. 2A. The diodes 230 may each include a doped semiconductor fin 220 that interfaces with a doped semiconductor well 210, the doped semiconductor fin 220 doped with carriers of the opposite type as that of the doped semiconductor well 210 (e.g., p+ doping of the semiconductor fins 220 and the doped semiconductor well 210 including an n-well). In the example of FIG. 2, the diodes 230 have a relatively large interface area between the doped semiconductor fins 220 and the doped semiconductor well 210 (the entire horizontal cross-sectional area of each of the fins 220). A large interface area is desirable because the diode current is proportional to the interface area.

The integrated circuit device structure 200 may be formed on or in a bulk semiconductor substrate (not shown). Many devices for which it would be useful to track temperature fluctuations, however, are not formed on or in bulk semiconductor substrates. By way of non-limiting example, fin field effect transistors (finFETS) may be formed on or in a silicon on insulator (SOI) substrate. It is more difficult to achieve a large interface area for diodes formed on or in a SOI substrate than on or in a bulk semiconductor substrate.

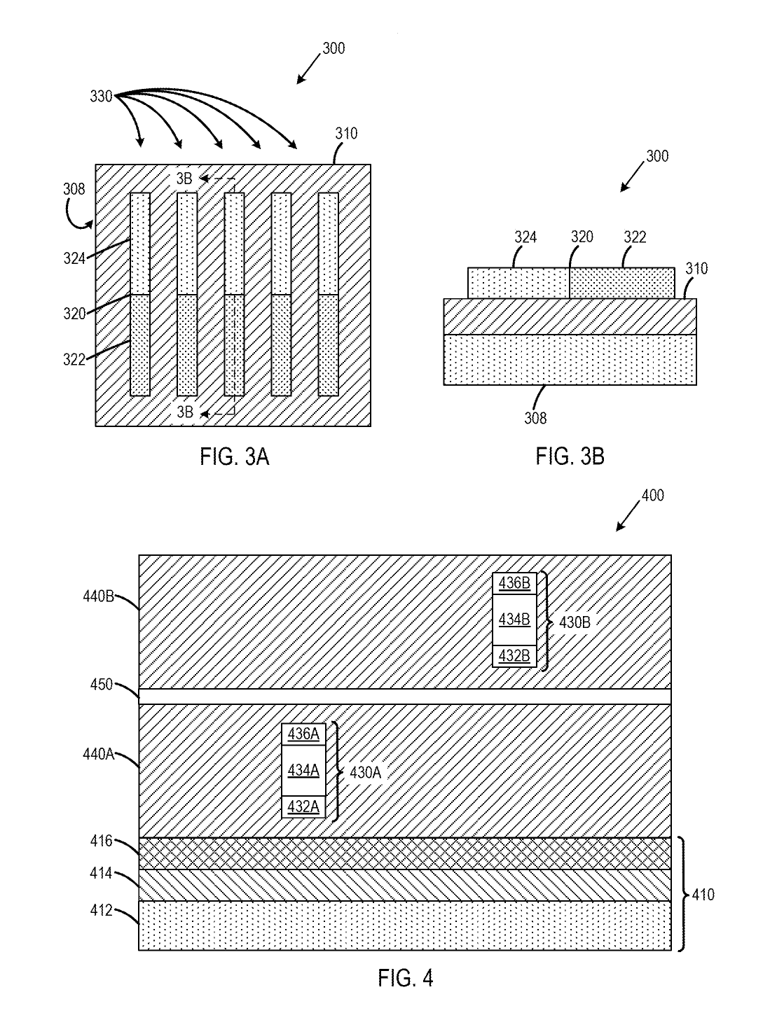

FIGS. 3A and 3B illustrate an example of p-n junction diodes 330 in an integrated circuit device structure 300. FIG. 3A is a simplified plan view of the integrated circuit device structure 300. FIG. 3B is a simplified cross-sectional view of the integrated circuit device structure 300 taken through line 3B of FIG. 3A. The diodes are formed on or in a SOI substrate. The diodes 330 may each include a semiconductor fin 320 on an oxide material 310 (e.g., the oxide of the SOI substrate, the oxide on a bulk semiconductor material 308). Each semiconductor fin 320 includes a p+ type doped region 322 and an n+ type doped region 324.

The p-n interface area of the diodes 330 is the vertical cross-sectional area of the semiconductor fins 320, which is relatively small compared to the p-n interface area of the diodes 230 of FIGS. 2A and 2B. As a result, the diodes 330 may be capable of only conducting a fraction of the current that the diodes 230 can conduct, assuming similar scale of the fins 320 and 220. This relatively low current may make it difficult to detect the temperature of the diodes 330, and therefore the diodes 330 may not be suitable for temperature monitoring.

Disclosed herein are electronic devices, integrated circuit structures, and computing devices including thin film, diode-based temperature sensors. These diode-based temperature sensors may be implemented within an interlayer dielectric (ILD) (backend diodes).

FIG. 4 is a simplified cross-sectional view of an electronic device 400, according to some embodiments. The electronic device 400 includes a SOI substrate 410 including a bulk semiconductor material 412, an oxide material 414, and a device layer 416. The electronic device 400 also includes one or more ILDs 440A, 440B and one or more metal layers 450 on the device layer 416. The electronic device 400 further includes one or more diodes 430A, 430B within the one or more ILDs 440A, 440B. In some embodiments, at least one of the one or more metal layers 450 may be located between at least one of the diodes 440B and the device layer 416.

The one or more diodes 430A, 430B include bandgap temperature sensors. The one or more diodes 430A, 430B include diode materials 434A, 434B between a first contact 432A, 432B and a second contact 432B, 436B. In some embodiments, and as illustrated in FIG. 4, at least a portion of the interlayer dielectric 440A, 440B is located between the one or more diodes 430A, 430B and the device layer 416.

In some embodiments, the device layer 416 may include temperature tracking circuitry operably coupled to the one or more diodes 430A, 430B. The temperature tracking circuitry is configured to detect changes in operational behavior of the one or more diodes 430A, 430B and correlate the changes in behavior of the one or more diodes 430A, 430B to changes in temperature of the one or more diodes 430A, 430B. The changes in temperature of the one or more diodes 430A, 430B may be correlated to temperatures of circuitry at various points in the electronic device 400.

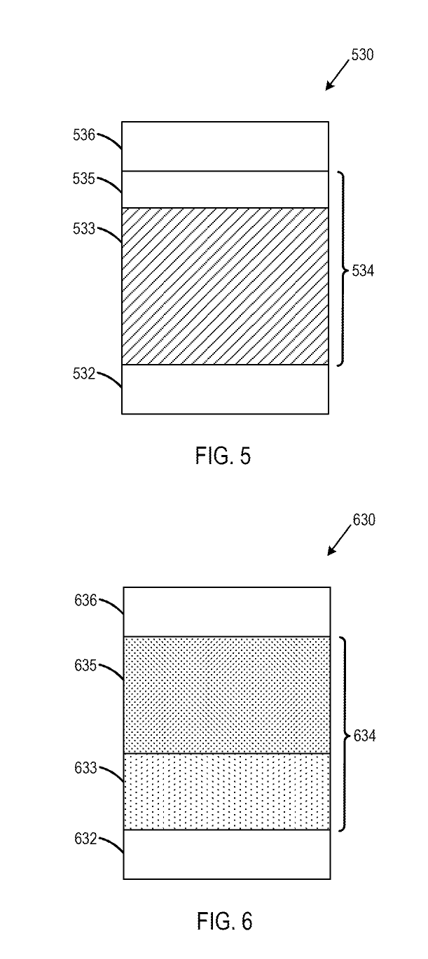

In some embodiments, at least one of the one or more diodes 430A, 430B includes a Shottky diode 530, as illustrated in FIG. 5. In some embodiments, at least one of the one or more diodes 430A, 430B includes a p-n junction diode 630, as illustrated in FIG. 6.

FIG. 5 is a simplified cross-sectional view of a Shottky diode 530, according to some embodiments. The Shottky diode 530 includes a pair of contacts 532, 536, and diode materials 534 between the contacts 532, 536. The diode materials 534 include an oxide semiconductor material 533 and an electrically conductive material 535 (e.g., a metal such as palladium (Pd)). By way of non-limiting example, the oxide semiconductor material 533 includes at least one of indium gallium zinc oxide (IGZO), zinc oxide (ZnO), or magnesium oxide (MgO).

FIG. 6 is a simplified cross-sectional view of a p-n junction diode 630, according to some embodiments. The p-n junction diode 630 includes a pair of contacts 632, 636, and diode materials 634 between the contacts 632, 636. The diode materials 634 include an n-doped region 633 and a p-doped region 635. By way of non-limiting example, the n-doped region 633 and the p-doped region 635 may include at least one amorphous or poly semiconductor material selected from silicon (Si), silicon germanium (SiGe), germanium (Ge), gallium arsenide (GaAs), indium arsenide (InAs), or combinations thereof.

Since the diode materials 534, 634 discussed above may be deposited using low temperature deposition, the diodes 530, 630 may be created in a backend of the electronic device 400 (e.g., within the ILD 440A, 440B).

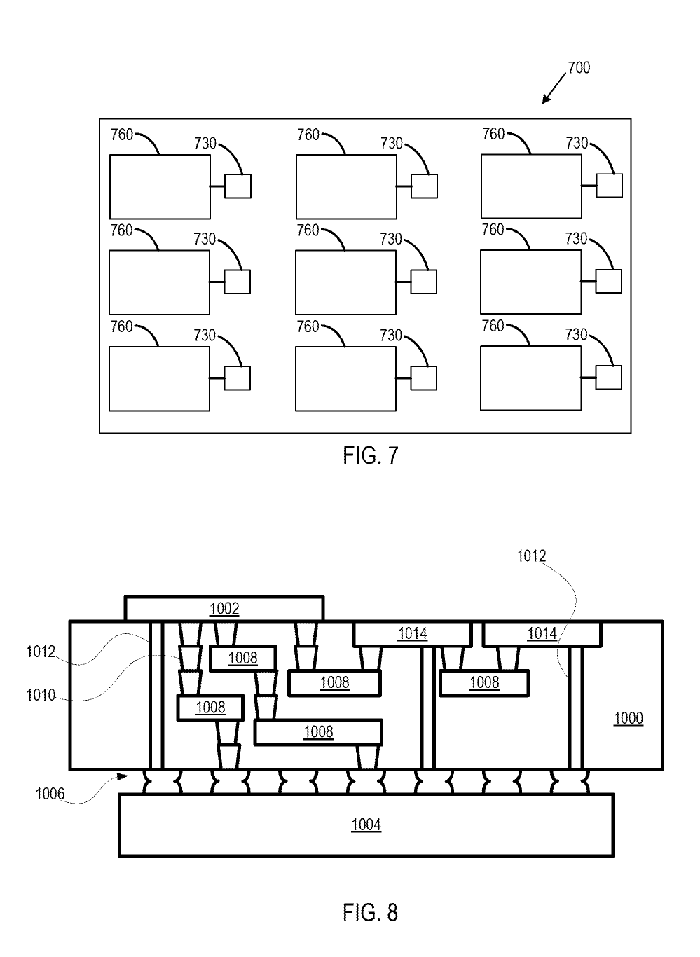

FIG. 7 is a simplified block diagram of an electronic device 700, according to some embodiments. As illustrated in FIG. 7, the electronic device 700 includes a plurality of control circuits 760 (e.g., located within a device layer of the electronic device 700, similar to the device layer 416 of FIG. 4) operably coupled to a plurality of diodes 730 configured to function as temperature sensors. Each of the diodes 730 may be similar to the diodes 430 discussed above with reference to FIG. 4. Each of the diodes 730 is configured to detect a temperature of one or more portions of the electronic device 700. Since heat issues can vary depending on location within the electronic device 700, it may be advantageous to employ more than one diode 730 within the same electronic device 700 at various locations (e.g., at various locations throughout an integrated circuit device structure).

In some embodiments, at least some of the portions of the electronic device 700 for which the diodes 730 are configured to monitor temperature include temperature sensitive devices. By way of non-limiting example, at least one of the diodes 730 may be configured to monitor a temperature of a selector device, a voltage controlled oscillator, other temperature sensitive device, or combinations thereof. Readings from the diodes 730 may be used by the control circuits 760 to take appropriate measures responsive to temperature fluctuations. For example, the control circuits 760 may scale back or discontinue operation of the devices for which the diodes 730 monitor temperature, trigger affirmative cooling systems (e.g., a ventilation fan, a liquid nitrogen system, etc.), compensate for changes in behavior of devices responsive to temperature fluctuations, or take other measures responsive to detections of temperature fluctuations via the diodes 730.

In some embodiments, the portions of the electronic device for which some of the diodes 730 are monitoring temperatures may include circuitry located within an ILD (e.g., similar to the ILD 440A, 440B of FIG. 4). By way of non-limiting example, the circuitry may include one or more memory arrays (e.g., a one selector, one resistor (1S-1R) memory array).

A plurality of transistors, such as metal-oxide-semiconductor field-effect transistors (MOSFET or simply MOS transistors), may be fabricated on or in a device layer (e.g., the device layer 416 of FIG. 4). In various implementations of the disclosure, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the disclosure may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode is formed on the gate dielectric and may consist of at least one P-type workfunction metal or N-type workfunction metal, depending on whether the transistor is to be a PMOS or an NMOS transistor. In some implementations, the gate electrode may consist of a stack of two or more metals, where one or more metals are workfunction metals and at least one metal is a fill metal. Further metals may be included for other purposes, such as a barrier material.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal will enable the formation of an NMOS gate electrode with a workfunction that is between about 3.9 eV and about 4.2 eV.

In some implementations, when viewed as a cross-section of the transistor along the source-channel-drain direction, the gate electrode may consist of a U-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the disclosure, the gate electrode may include a combination of U-shaped structures and planar, non-U-shaped structures. For example, the gate electrode may consist of one or more U-shaped metals formed atop one or more planar, non-U-shaped materials.

In some implementations of the disclosure, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. In further embodiments, one or more metals and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

FIG. 8 illustrates an interposer 1000 that includes one or more embodiments of the disclosure. The interposer 1000 is an intervening substrate used to bridge a first substrate 1002 to a second substrate 1004. The first substrate 1002 may be, for instance, an integrated circuit die. The second substrate 1004 may be, for instance, a memory module, a computer motherboard, or another integrated circuit die. In some embodiments, the first substrate 1002, the second substrate 1004, or a combination thereof includes a diode 430A, 430B, 530, 630, or 730, as discussed above with reference to FIGS. 4-7 above. Generally, the purpose of an interposer 1000 is to spread a connection to a wider pitch or to reroute a connection to a different connection. For example, an interposer 1000 may couple an integrated circuit die to a ball grid array (BGA) 1006 that can subsequently be coupled to the second substrate 1004. In some embodiments, the first and second substrates 1002/1004 are attached to opposing sides of the interposer 1000. In other embodiments, the first and second substrates 1002/1004 are attached to the same side of the interposer 1000. And in further embodiments, three or more substrates are interconnected by way of the interposer 1000.

The interposer 1000 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 1008 and vias 1010, including but not limited to through-silicon vias (TSVs) 1012. The interposer 1000 may further include embedded devices 1014, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 1000.

In accordance with embodiments of the disclosure, apparatuses or processes disclosed herein may be used in the fabrication of interposer 1000.

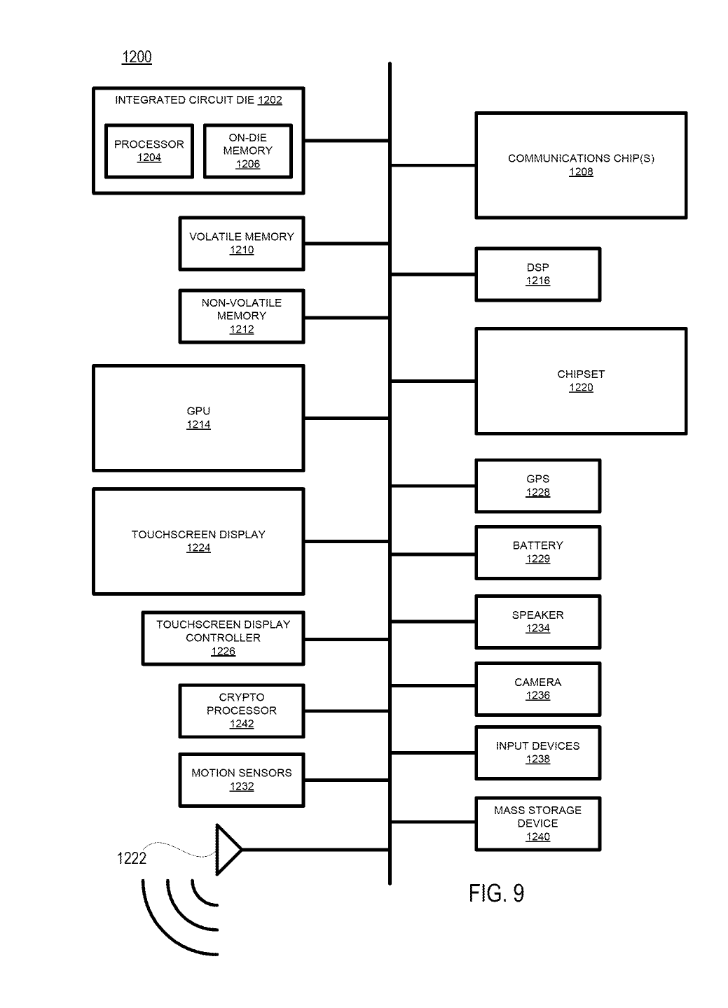

FIG. 9 illustrates a computing device 1200 in accordance with one embodiment of the disclosure. The computing device 1200 may include a number of components. In one embodiment, these components are attached to one or more motherboards. In an alternate embodiment, some or all of these components are fabricated onto a single system-on-a-chip (SoC) die, such as an SoC used for mobile devices. The components in the computing device 1200 include, but are not limited to, an integrated circuit die 1202 and at least one communications chip 1208 (e.g., a communications logic unit). In some implementations the communications chip 1208 is fabricated within the integrated circuit die 1202 while in other implementations the communications logic unit 1208 is fabricated in a separate integrated circuit chip that may be bonded to a substrate or motherboard that is shared with or electronically coupled to the integrated circuit die 1202. The integrated circuit die 1202 may include a processor 1204 (e.g., a CPU) as well as on-die memory 1206, often used as cache memory, which can be provided by technologies such as embedded DRAM (eDRAM), SRAM, or spin-transfer torque memory (STT-MRAM).

Computing device 1200 may include other components that may or may not be physically and electrically coupled to the motherboard or fabricated within an SoC die. These other components include, but are not limited to, volatile memory 1210 (e.g., DRAM), non-volatile memory 1212 (e.g., ROM or flash memory), a graphics processing unit (GPU) 1214, a digital signal processor (DSP) 1216, a crypto processor 1242 (e.g., a specialized processor that executes cryptographic algorithms within hardware), a chipset 1220, at least one antenna 1222 (in some implementations two or more antennas may be used), a display or a touchscreen display 1224, a touchscreen display controller 1226, a battery 1229 or other power source (not shown), a power amplifier (not shown), a voltage regulator (not shown), a global positioning system (GPS) device 1228, a compass (not shown), one or more motion sensors 1232 (e.g., a motion coprocessor such as an accelerometer, a gyroscope, a compass, etc.), a microphone (not shown), a speaker 1234, a camera 1236, user input devices 1238 (such as a keyboard, mouse, stylus, and touchpad), and a mass storage device 1240 (such as hard disk drive, compact disk (CD), digital versatile disk (DVD), and so forth). The computing device 1200 may incorporate further transmission, telecommunication, or radio functionality not already described herein. In some implementations, the computing device 1200 includes a radio that is used to communicate over a distance by modulating and radiating electromagnetic waves in air or space. In further implementations, the computing device 1200 includes a transmitter and a receiver (or a transceiver) that is used to communicate over a distance by modulating and radiating electromagnetic waves in air or space.

The communications chip 1208 may include a communications logic unit configured to transfer data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communications logic unit 1208 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Infrared (IR), Near Field Communication (NFC), Bluetooth, derivatives thereof, as well as any other wireless protocols that are designated as 3G, 4G, 5G, and beyond. The computing device 1200 may include a plurality of communications chips 1208. For instance, a first communications chip 1208 may be dedicated to shorter range wireless communications such as Wi-Fi, NFC, and Bluetooth and a second communications chip 1208 may be dedicated to longer range wireless communications such as GPS, EDGE, GPRS, CDMA, WiMAX, LTE, Ev-DO, and others.

The processor 1204 of the computing device 1200 includes a diode 430A, 430B, 530, 630, or 730, as discussed above with reference to FIGS. 4-7 above. The term “processor” may refer to any device or portion of a device that processes electronic data from registers and/or memory to transform that electronic data into other electronic data that may be stored in registers and/or memory.

The communications logic unit 1208 may also include a diode 430A, 430B, 530, 630, or 730, as discussed above with reference to FIGS. 4-7 above.

In further embodiments, another component housed within the computing device 1200 may contain a diode 430A, 430B, 530, 630, or 730, as discussed above with reference to FIGS. 4-7 above.

In various embodiments, the computing device 1200 may be a laptop computer, a netbook computer, a notebook computer, an ultrabook computer, a smartphone, a dumbphone, a tablet, a tablet/laptop hybrid, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 1200 may be any other electronic device that processes data.

In some embodiments, the computing device 1200 includes an integrated circuit device structure. The integrated circuit device structure includes an ILD and a bandgap temperature sensor within the ILD. The integrated circuit device structure also includes control circuitry electrically connected to the bandgap temperature sensor, the control circuitry configured to detect a temperature of the bandgap temperature sensor responsive to temperature-correlated behavior of the bandgap temperature sensor. In some embodiments, the computing device also includes electronic circuitry proximate to the bandgap temperature sensor, the control circuitry configured to correlate a detected temperature of the bandgap temperature sensor with a temperature of the electronic circuitry. In some embodiments, the bandgap temperature sensor includes a diode. In some embodiments, at least one of the processor 1204, the memory 1206, 1210, 1212, the graphics processing unit 1214, the antenna 1222, the display 1224, the power amplifier (not shown), or the voltage regulator (not shown) includes the integrated circuit device structure.

The following is a non-exhaustive list of example embodiments that fall within the scope of the disclosure. In order to avoid complexity in providing the disclosure, not all of the examples listed below are separately and explicitly disclosed as having been contemplated herein as combinable with all of the others of the examples listed below and other embodiments disclosed hereinabove. Unless one of ordinary skill in the art would understand that these examples listed below, and the above disclosed embodiments, are not combinable, it is contemplated within the scope of the disclosure that such examples and embodiments are combinable.

### Example 1

An electronic device, comprising: a diode comprising diode materials between a first contact and a second contact; a device layer of an integrated circuit device structure; and at least a portion of an interlayer dielectric between the diode and the device layer.

### Example 2

The electronic device of claim 1, wherein the diode comprises a Shottky diode.

### Example 3

The electronic device of claim 2, wherein the diode materials comprise an oxide semiconductor and an electrically conductive material.

### Example 4

The electronic device of claim 3, wherein the oxide semiconductor comprises at least one of indium gallium zinc oxide (IGZO), zinc oxide (ZnO), or magnesium oxide (MgO).

### Example 5

The electronic device of claim 3, wherein the electrically conductive material comprises a metal.

### Example 6

The electronic device of claim 1, wherein the diode comprises a p-n junction diode.

### Example 7

The electronic device of claim 6, wherein the diode materials comprise at least one amorphous or poly material selected from the group consisting of silicon (Si), silicon germanium (SiGe), germanium (Ge), gallium arsenide (GaAs), and indium arsenide (InAs).

### Example 8

The electronic device of claim 1, wherein the diode comprises a bandgap temperature sensor.

### Example 9

The electronic device of claim 8, further comprising temperature tracking circuitry operably coupled to the diode and configured to detect changes in operational behavior of the diode and correlate the changes in behavior of the diode to changes in temperature of the diode.

### Example 10

The electronic device of claim 1, further comprising at least one metal layer between the diode and the device layer.

### Example 11

An integrated circuit device structure, comprising: a plurality of different portions of electronic circuitry; a plurality of temperature sensors located within an interlayer dielectric (ILD), each of the plurality of temperature sensors at least partially thermally coupled to one of the plurality of different portions of electronic circuitry; and temperature detection circuitry electrically coupled to at least one of the plurality of temperature sensors, the temperature detection circuitry configured to trigger a temperature compensation measure responsive to a detection that a temperature of the at least one of plurality of temperature sensors is outside of a predetermined threshold boundary.

### Example 12

The integrated circuit device structure of claim 11, wherein the temperature detection circuitry is located within a device layer on which the ILD is formed.

### Example 13

The integrated circuit device structure of claim 11, wherein the ILD includes a plurality of interconnect layers, and the plurality of temperature sensors is distributed within at least two of the plurality of interconnect layers.

### Example 14

The integrated circuit device structure of claim 11, wherein the temperature compensation measure includes at least one measure selected from the group consisting of a scale-back in operation, a discontinuance of operation, a trigger to activate a cooling system, or a compensation for changes in behavior of devices responsive to temperature fluctuations.

### Example 15

The integrated circuit device structure of claim 14, wherein the cooling system comprises a fan.

### Example 16

The integrated circuit device structure of claim 11, wherein at least one of the plurality of temperature sensors comprises a p-n junction diode.

### Example 17

The integrated circuit device structure of claim 11, wherein at least one of the plurality of temperature sensors comprises a Shottky diode.

### Example 18

A computing device, comprising: an integrated circuit device structure comprising: an interlayer dielectric; a bandgap temperature sensor within the interlayer dielectric; and control circuitry electrically connected to the bandgap temperature sensor, the control circuitry configured to detect a temperature of the bandgap temperature sensor responsive to temperature-correlated behavior of the bandgap temperature sensor.

### Example 19

The computing device of claim 18, further comprising: a processor mounted on a substrate; a memory unit capable of storing data; a graphics processing unit; an antenna within the computing device; a display on the computing device; a power amplifier within the processor; and a voltage regulator within the processor; wherein at least one of the processor, the memory unit, the graphics processing unit, the antenna, the display, the power amplifier, or the voltage regulator includes the integrated circuit device structure.

### Example 20

The computing device of claim 18, wherein the integrated circuit device structure further comprises electronic circuitry proximate to the bandgap temperature sensor, the control circuitry configured to correlate a detected temperature of the bandgap temperature sensor with a temperature of the electronic circuitry.

### Example 21

The computing device of claim 18, wherein the bandgap temperature sensor comprises a diode.

### Example 22

A means for operating at least a portion of any one of the devices of Examples 1-21.

### Example 23

A means for forming at least a portion of any one of the devices of Examples 1-21.

### Example 24

A method of operating at least a portion of any one of the devices of Examples 1-21.

### Example 25

A method of forming at least a portion of any one of the devices of Examples 1-21.

### Example 26

A computer-readable storage medium (e.g., a non-transitory computer-readable storage medium) having computer-readable instructions stored thereon, the computer-readable instructions configured to instruct one or more processors to perform at least a portion of the method of Example 25.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. An electronic device, comprising:
a diode comprising diode materials between a first contact and a second contact;
a device layer of an integrated circuit device structure; and
at least a portion of an interlayer dielectric between the diode and the device layer.

2. The electronic device of claim 1, wherein the diode comprises a Shottky diode.

3. The electronic device of claim 2, wherein the diode materials comprise an oxide semiconductor and an electrically conductive material.

4. The electronic device of claim 3, wherein the oxide semiconductor comprises at least one of indium gallium zinc oxide (IGZO), zinc oxide (ZnO), or magnesium oxide (MgO).

5. The electronic device of claim 3, wherein the electrically conductive material comprises a metal.

6. The electronic device of claim 1, wherein the diode comprises a p-n junction diode.

7. The electronic device of claim 6, wherein the diode materials comprise at least one amorphous or poly material selected from the group consisting of silicon (Si), silicon germanium (SiGe), germanium (Ge), gallium arsenide (GaAs), and indium arsenide (InAs).

8. The electronic device of claim 1, wherein the diode comprises a bandgap temperature sensor.

9. The electronic device of claim 8, further comprising temperature tracking circuitry operably coupled to the diode and configured to detect changes in operational behavior of the diode and correlate the changes in behavior of the diode to changes in temperature of the diode.

10. The electronic device of claim 1, further comprising at least one metal layer between the diode and the device layer.

11. An integrated circuit device structure, comprising:
a plurality of different portions of electronic circuitry;
a plurality of temperature sensors located within an interlayer dielectric (ILD), each of the plurality of temperature sensors at least partially thermally coupled to one of the plurality of different portions of electronic circuitry; and
temperature detection circuitry electrically coupled to at least one of the plurality of temperature sensors, the temperature detection circuitry configured to trigger a temperature compensation measure responsive to a detection that a temperature of the at least one of plurality of temperature sensors is outside of a predetermined threshold boundary.

12. The integrated circuit device structure of claim 11, wherein the temperature detection circuitry is located within a device layer on which the ILD is formed.

13. The integrated circuit device structure of claim 11, wherein the ILD includes a plurality of interconnect layers, and the plurality of temperature sensors is distributed within at least two of the plurality of interconnect layers.

14. The integrated circuit device structure of claim 11, wherein the temperature compensation measure includes at least one measure selected from the group consisting of a scale-back in operation, a discontinuance of operation, a trigger to activate a cooling system, or a compensation for changes in behavior of devices responsive to temperature fluctuations.

15. The integrated circuit device structure of claim 14, wherein the cooling system comprises a fan.

16. The integrated circuit device structure of claim 11, wherein at least one of the plurality of temperature sensors comprises a p-n junction diode.

17. The integrated circuit device structure of claim 11, wherein at least one of the plurality of temperature sensors comprises a Shottky diode.

18. A computing device, comprising:
an integrated circuit device structure comprising:
an interlayer dielectric;
a bandgap temperature sensor within the interlayer dielectric; and
control circuitry electrically connected to the bandgap temperature sensor, the control circuitry configured to detect a temperature of the bandgap temperature sensor responsive to temperature-correlated behavior of the bandgap temperature sensor.

19. The computing device of claim 18, further comprising:
a processor mounted on a substrate;
a memory unit capable of storing data;
a graphics processing unit;
an antenna within the computing device;
a display on the computing device;
a power amplifier within the processor; and
a voltage regulator within the processor;
wherein at least one of the processor, the memory unit, the graphics processing unit, the antenna, the display, the power amplifier, or the voltage regulator includes the integrated circuit device structure.

20. The computing device of claim 18, wherein the integrated circuit device structure further comprises electronic circuitry proximate to the bandgap temperature sensor, the control circuitry configured to correlate a detected temperature of the bandgap temperature sensor with a temperature of the electronic circuitry.

21. The computing device of claim 18, wherein the bandgap temperature sensor comprises a diode.
